(19) United States
(12) Patent Application Publication
(10) Pub. No.: US 2006/0284316 A1
(43) Pub. Date: Dec. 21, 2006

(54) Chip size package

(76) Inventor: Ji Mook Kim, Chungcheongbuk-do (KR)

Correspondence Address: LADAS & PARRY LLP, 224 SOUTH MICHIGAN AVENUE, SUITE 1600, CHICAGO, IL, 60604, US

(21) Appl. No.: 11/471,079

(22) Filed: Jun. 20, 2006

(30) Foreign Application Priority Data
Jun. 21, 2005 (KR) 10-2005-0053634

(51) Int. Cl. H01L 23/48

(52) U.S. Cl. 257/738

(57) ABSTRACT

A chip size package comprises a substrate to one surface of which a chip is mounted, a solder ball land formed on the other surface of the substrate and having a projecting center part, a solder mask formed on the other surface of the substrate and having an opening for exposing the solder ball land and a portion of the other surface of the substrate, and a solder ball fused to the solder ball land. As the chip size package has a combined SMD type and NSMD type solder ball land structure, the adhesion force between a solder ball land and a solder ball is reliably increased, and the advantages of SMD type and NSMD type solder ball lands is obtained.

### BACKGROUND OF THE INVENTION

1. Field of the Invention

The present invention relates, in general, to a chip size package, and more particularly, to a chip size package in which a solder ball land for mounting of a solder ball has a combined SMD and NSMD type.

2. Description of the Related Art

These days, as electronic products have been miniaturized, the space for mounting a semiconductor device has been decreased. Further, as the electronic products have multi-functionality and high performance, the number and the kinds of semiconductors for ensuring multi-functionality and high performance has been increased. In this regard, in order to increase mounting efficiency per unit volume, a package must have a small size, a thin thickness and a light weight. In an effort to meet these requirements, a chip size package having substantially the same size as a chip has been developed and commercialized.

The chip size package is connected to a printed circuit board using solder balls fused to a solder ball land formed on the lower surface of a substrate, instead of a lead frame. As a solder ball land structure, an SMD (solder mask defined) type and an NSMD (non solder mask defined) type as shown in FIGS. 1 and 2 are adopted in the conventional art.

First referring to FIG. 1, in an SMD type solder ball land structure, a pattern connection section 14 and the peripheral part 10a of a solder ball land 10 connected to the pattern connection section 14 are covered by a solder mask 16, and the center part 10b of the solder ball land 10 is exposed to the outside through an opening 16a in the solder mask 16. That is to say, in the SMD type solder ball land structure, the solder ball land 10 which is formed of copper and has a circular shape is deposited on a substrate (not shown), and nickel and gold are sequentially plated on the surface of the solder ball land 10 so that a solder ball (not shown) can be easily fused to the solder ball land 10. Then, the solder mask 16 is deposited to cover the peripheral part 10a of the solder ball land 10 and the substrate.

However, in this SMD type solder ball land structure, when forming a module, while the shear value of the solder ball is excellent, adhesion force between the solder ball land 10 and the solder ball is inferior. Therefore, when testing the reliability of a solder ball joint by changing a temperature such as in a thermal cycle, a problem is caused in that the solder ball is easily detached from the solder ball land 10.

Next referring to FIG. 2, in an NSMD type solder ball land structure, a portion 24a of a pattern connection section 24 is covered by a solder mask 26, and the remaining portion 24b of the pattern connection section 24, a solder ball land 20 and a portion of a substrate 1 are exposed to the outside through an opening 26a in the solder mask 26. That is to say, in the NSMD type solder ball land structure, the solder ball land 20 is deposited on the surface of the substrate 1, and nickel and gold are sequentially plated on the surface of the solder ball land 20. The solder mask 26 is deposited such that the remaining portion 24b of the pattern connection section 24, the solder ball land 20 and the portion of the substrate 1 are exposed to the outside.

However, in this NSMD type solder ball land structure, while the reliability of a solder ball joint is superior, a problem is caused in that a pattern crack phenomenon in which the pattern connection section 24 connected to the solder ball land 20 is broken or a solder ball land separation phenomenon in which the solder ball land 20 is separated from the substrate 1 occurs.

### SUMMARY OF THE INVENTION

Accordingly, the present invention has been made in an effort to solve the problems occurring in the related art, and an object of the present invention is to provide a chip size package in which the advantages of SMD type and NSMD type solder ball lands are combined to improve resistance to thermal and mechanical deformation due to external factors.

In order to achieve the above object, according to one aspect of the present invention, there is provided a chip size package comprising a substrate to one surface of which a chip is mounted; a solder ball land formed on the other surface of the substrate and having a projecting center part; a solder mask formed on the other surface of the substrate and having an opening for exposing the solder ball land and a portion of the other surface of the substrate; and a solder ball fused to the solder ball land.

According to another aspect of the present invention, the solder ball land has a plurality of leg parts which extend radially from a lower end of the projecting center part.

According to still another aspect of the present invention, the plurality of leg parts define a Y-shaped configuration.

According to yet still another aspect of the present invention, the solder ball is fused to the entire area of the projecting center part of the solder ball land and portions of the plurality of leg parts.

### BRIEF DESCRIPTION OF THE DRAWINGS

The above objects, and other features and advantages of the present invention will become more apparent after a reading of the following detailed description when taken in conjunction with the drawings, in which:

FIG. 1 is a plan view illustrating a conventional SMD type solder ball land;

FIG. 2 is a plan view illustrating a conventional NSMD type solder ball land;

FIG. 3 is a cross-sectional view illustrating a chip size package in accordance with an embodiment of the present invention; and

FIG. 4 is a plan view illustrating a state in which a solder ball is bonded to a solder ball land in FIG. 3.

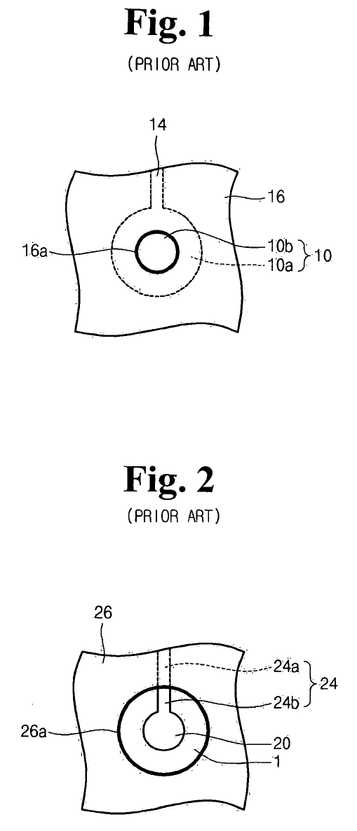

### DETAILED DESCRIPTION OF PREFERRED EMBODIMENTS

Reference will now be made in greater detail to a preferred embodiment of the invention, an example of which is illustrated in the accompanying drawings. Wherever possible, the same reference numerals will be used throughout the drawings and the description to refer to the same or like parts.

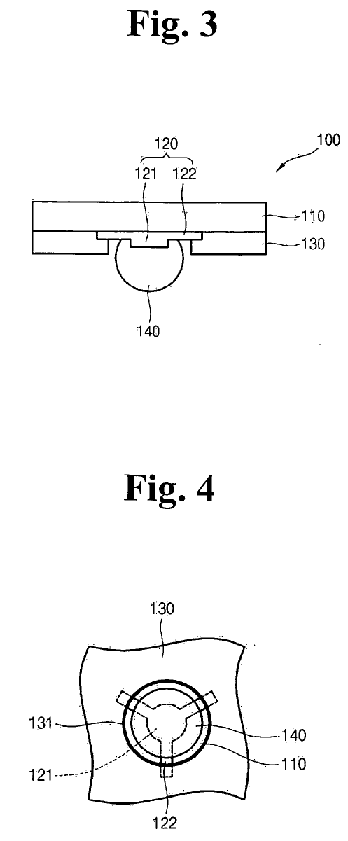

FIG. 3 is a cross-sectional view illustrating a chip size package in accordance with an embodiment of the present invention, and FIG. 4 is a plan view illustrating a state in which a solder ball is bonded to a solder ball land in FIG. 3.

Referring to the drawings, a chip size package 100 includes a substrate 110 to one surface of which a chip (not shown) is mounted, a solder ball land 120 formed on the other surface of the substrate 110, a solder mask 130 formed on the other surface of the substrate 110 and having an opening 131 for exposing the solder ball land 120 and a portion of the other surface of the substrate 110, and a solder ball 140 fused to the solder ball land 120.

The solder ball land 120 formed on the other surface of the substrate 110 serves as a section to which the solder ball 140 is coupled, and has a three-dimensional overall shape. The center part 121 of the solder ball land 120 projects from the other surface of the substrate 110, and a plurality of leg parts 122 radially extend from the lower end of the projecting center part 121. That is to say, the center part 121 and the plurality of leg parts 122 define a stepped contour having different heights.

The plurality of leg parts 122 define a Y-shaped configuration. The plurality of leg parts 122 function to increase a contact area when fusing the solder ball 140 to the solder ball land 120 and to electrically connect the chip and the solder ball 140 with each other.

In the structure of the solder ball land 120, the solder ball land 120 is formed on the center portion of the substrate 110, and the solder mask 130 is formed on the solder ball land 120 and the substrate 110. That is to say, the solder ball land 120 and the portion of the substrate 110 are exposed to the outside through the opening 131 of the solder mask 130 which is deposited on the substrate 110 and the solder ball land 120. The solder ball land 120 has the Y-shaped configuration obtained by partial etching of a circular configuration. The substrate 110 is partially exposed through the etched portions. In this way, the structure of the solder ball land 120 has a combined SMD and NSMD type. In other words, the NSMD type is achieved due to the fact that the solder ball land 120 and the portion of the surface of the substrate 110 are exposed, and the SMD type is achieved due to the fact that the portion of the substrate 110 is partially covered by covering the leg parts 122 of the solder ball land 120.

The solder ball 140 is connected to the solder ball land 120 to electrically connect the package to an external device. The solder ball 140 is fused to the entire area of the center part 121 of the solder ball land 120 and to portions of the plurality of the leg parts 122.

The chip size package 100 constructed as mentioned above has a combined SMD and NSMD type and accomplishes the respective advantages of the SMD and NSMD types. Namely, as the solder ball 140 is fused to the entire area of the center part 121 of the solder ball land 120 and portions of the plurality of the leg parts 122 which are exposed to the outside through the opening 131, the adhesion force of the solder ball 140 can be increased.

As is apparent from the above description, the chip size package according to the present invention provides advantages in that, since the chip size package has a combined SMD type and NSMD type solder ball land structure, the adhesion force between a solder ball land and a solder ball can be reliably increased, and the advantages of SMD type and NSMD type solder ball lands can be obtained.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A chip size package comprising:
a substrate to one surface of which a chip is mounted;
a solder ball land formed on the other surface of the substrate and having a projecting center part;
a solder mask formed on the other surface of the substrate and having an opening for exposing the solder ball land and a portion of the other surface of the substrate; and
a solder ball fused to the solder ball land.

2. The chip size package as set forth in claim 1, wherein the solder ball land has a plurality of leg parts which extend radially from a lower end of the projecting center part.

3. The chip size package as set forth in claim 2, wherein the plurality of leg parts define a Y-shaped configuration.

4. The chip size package as set forth in claim 2, wherein the solder ball is fused to the entire area of the projecting center part of the solder ball land and portions of the plurality of leg parts.
